(19) United States
(12) Patent Application Publication
(10) Pub. No.: US 2010/0129949 A1
(43) Pub. Date: May 27, 2010

(54) INCREASING SOLAR CELL EFFICIENCY WITH SILVER NANOWIRES

(76) Inventors: Chang Chen, Huntersville, NC (US); Yue Ma, Shandong (CN)

Correspondence Address: HAMMER & ASSOCIATES, P.C., 3125 SPRINGBANK LANE, SUITE G, CHARLOTTE, NC, 28226, US

(21) Appl. No.: 12/624,736

(22) Filed: Nov. 24, 2009

Related U.S. Application Data
(60) Provisional application No. 61/117,596, filed on Nov. 25, 2008.

(51) Int. Cl. H01L 31/18

(52) U.S. Cl. 438/57; 257/E31.119; 977/762

(57) ABSTRACT

A method for improving the performance and efficiency of a solar cell comprising the steps of: providing a plurality of silver nanowires and depositing a layer of the silver nanowires onto an emitter surface of the solar cell.

### RELATED APPLICATION

This application claims the benefit of co-pending provisional application Ser. No. 61/117,596 filed Nov. 25, 2008.

### FIELD OF THE INVENTION

The invention relates to an increase of solar cell efficiency through the incorporation of silver nanowires therein.

### BACKGROUND OF THE INVENTION

Solar energy is considered to be the source of nearly all energy forms on the earth. Photovoltaic solar cells are a simple and effective method of harnessing the limitless power of solar energy. Photovoltaic devices such as solar cells are unique in that they directly convert the incident light irradiation into electricity without noise, pollution or moving parts. This makes solar cells robust, reliable, long lasting, and clean.

The efficiency of the solar cell is the most commonly used parameter to judge the performance of a solar cell. It is defined as the ratio of energy output from the solar cell to input energy from the light irradiation, mathematical expressed as:

eff=J_{sc}*V_{oc}*FF/Pᵢₙ

where the J_{sc} is the short circuit current density, Voc the open circuit voltage, FF the fill factor, and Pᵢₙthe incident light power density. In the industrial silicon solar cells, the FF factor can typically vary from 74% to 79%, therefore has a strong impact on the final cell efficiency.

In a working solar cell, the generated electrons have to travel through the emitter before they can be collected. Therefore, the emitter sheet resistance (R_{□}) and the space between the two electrodes are important factors on limiting the FF. Apparently, the lower R_{□}and the shorter the electrode spacing, the higher the FF. Unfortunately, the J_{sc} decreases with reduced R_{□}(more recombination) and decreased electrode spacing (more shadowing). It seems contradictory to obtain both of high J_{sc} and high FF.

A need exists for improving the performance and efficiency of photovoltaic solar cells. Along with this need is a desire for the improvements to be inexpensive in terms of labor, materials, and energy. Currently, the performance and efficiency of solar cells is limited due to high energy requirements and production costs. In this invention we propose a novel solution on improving the performance and efficiency of the solar cells, based on deposition a network of silver nanowires on the emitter surface of the solar cell by spraying or spinning a silver nanowire suspension. The fill factor and the efficiency of the solar cell with silver nanowires increases, while at the same time without affecting the emitter sheet resistance (R_{□}) and the electrode shadowing area. Additionally, in this invention we propose a novel solution on improving FF and efficiency, while at the same time without affecting the R_{□}and the electrode shadowing, by depositing a network of silver nanowires on the emitter surface through a technique of spraying or spinning a silver nanowire suspension.

### SUMMARY OF THE INVENTION

A method for improving the performance and efficiency of a solar cell comprising the steps of: providing a plurality of silver nanowires and depositing a layer of the silver nanowires onto an emitter surface of the solar cell.

### BRIEF DESCRIPTION OF THE DRAWINGS

FIGS. 1A and 1B are low- and high-magnification SEM images of the silver nanowires with diameter of ˜200 nm.

FIG. 2A is a TEM image of silver nanowire with diameter of ˜100 nm. The insert shows the electron diffraction pattern of a silver nanowire.

FIG. 2B shows a UV-vis absorption spectrum of silver nanowires.

FIG. 3 shows an optical image of a silicon solar cell coated by silver nanowires.

FIG. 4 shows the role of silver nanowires in the solar cells.

FIG. 5 shows the I-V curve of the bare silicon solar cell with silver nanowires.

FIG. 6 shows the I-V curve of the bare silicon solar cell without silver nanowires.

### DETAILED DESCRIPTION

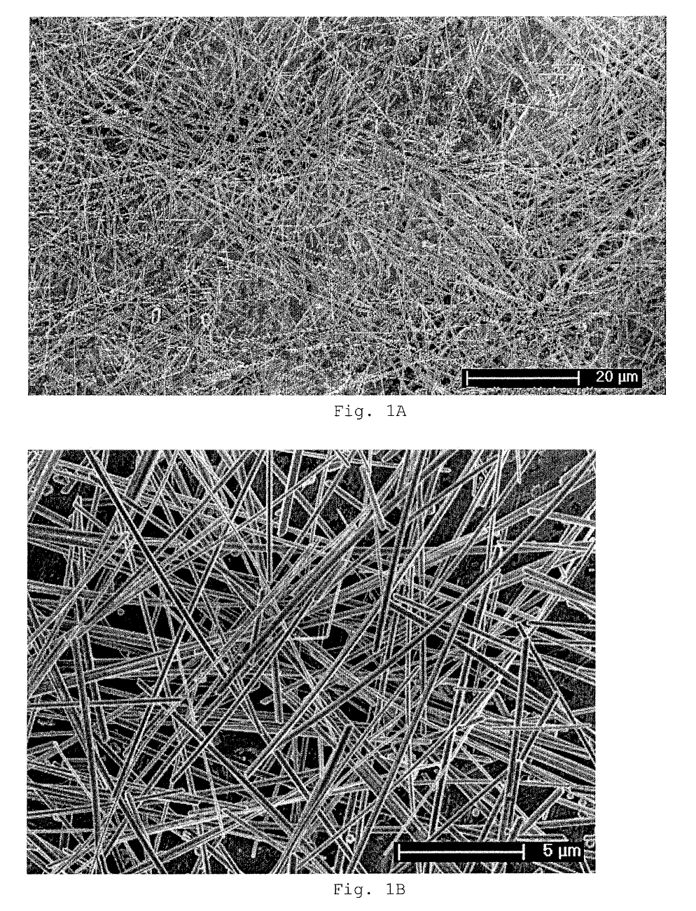

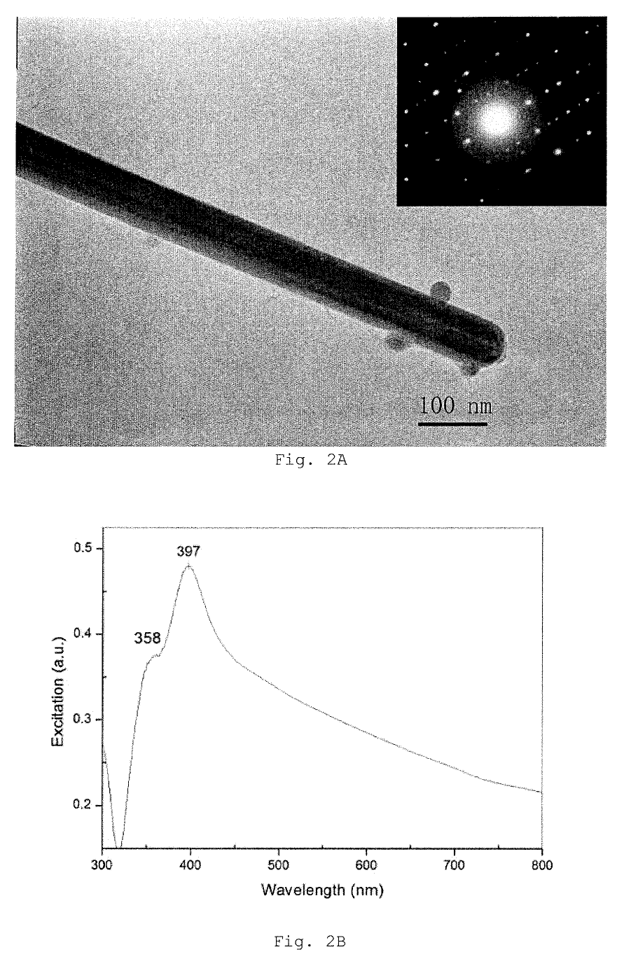

Silver nanowires are one of the most important nanowires studied today. This is due to the high electrical and thermal conductivity properties of silver as well as the plasmonic properties dependent on the morphology of the silver nanostructure. A variety of effective chemical methods have been utilized to prepare silver nanowires. For example, porous or solid template directed synthesis, biomimetic synthesis, molecular self-assembled directed synthesis, polyol process, and wet chemical synthesis. Currently, industrial mass produced silver nanowires are also available, such as the SNW serials from Filigreenanotech, INC. The morphology of such silver nanowires was observed by SEM (as shown in FIGS. 1A and 1B). The TEM image and SAED pattern (FIG. 2A) illustrate that the silver nanowires are the twinned crystal structures with a better electronic conductance. The optical property of the silver nanowires may be measured by UV-vis spectroscopy (FIG. 2B).

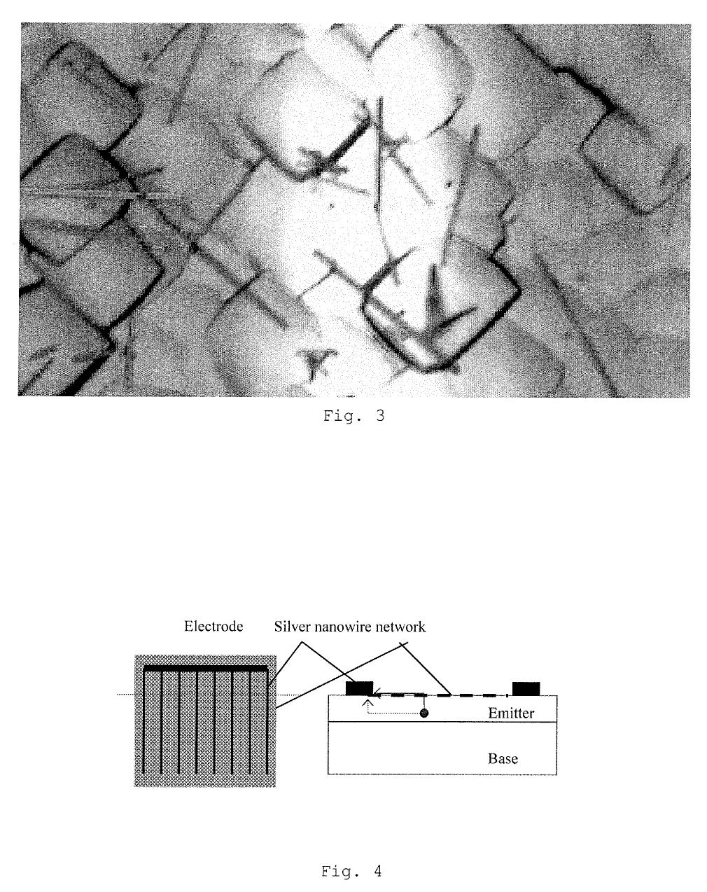

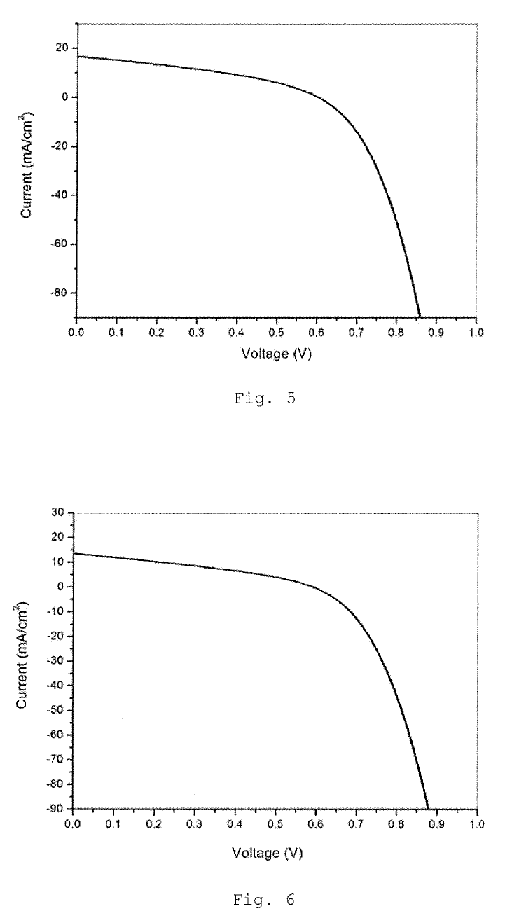

Due to the one dimensional morphology, silver nanowires tend to form a conductive network on both flat surfaces and rough surfaces. In the instant invention, the silver nanowires were deposited on the passivated emitter surface of the solar cells, forming a conductive network to reduce the effective series resistance and the effective electrode spacing. As shown in FIG. 3, the bright, wide belt in the middle of the picture is a silver finger electrode, while the narrow lines around it are silver nanowires. Additionally, the crystal structure of the silver nanowires also results in an improved conductive performance. As shown in FIG. 4, the top view of solar cell having a silver nanowire network on the emitter surface is on the left and the cross-section is on the right. As compared to each emitter both laterally and vertically, the electron can travel much easier through the emitter vertically and then via the conductive silver nanowire network. The short-way of silver nanowire-based conductive network reduces the loss of the electrons, resulting in an improvement on the current intensity as well as the filled factor of the solar cell. FIG. 5 and FIG. 6 show the I-V curves measured from the silicon solar cell with and without silver nanowires, respectively. It clearly demonstrates that the solar cell with silver nanowires realizes superior performance when compared to one without silver nanowires.

The surface plasmons (SP) property of the silver nanowires is believed to influence the solar cell on the shadowing effect. The UV-vis spectrum (FIG. 2B) shows that silver nanowires with uniform diameter maximally absorb and scatter light with the wavelength at around 400 nm which is not the main absorption wave band of the solar cell. Specifically, there are three factors related to the optical properties of silver nanowires which have affects on the solar performance. The first one is that the nanoscaled size of the silver nanowires, less than 300 nm in the instant invention, permits light to go round them by the optical diffraction law. It results in a positive effect on the performance of the solar cell. The second one is the scattering of the light by the silver nanowires. The scattered light can be reflected back by the multi-layers above the emitter surface. It doesn't affect the performance of the solar cell. The third one is the absorption of the light by the silver nanowires. The absorbed light converts into the surface plasmonics propagation inside the silver nanowires. This SP waves could reemit at the ends of the silver nanowires and be absorbed by the solar cell again. However, SP waves also decline inside silver and the dielectric materials quickly. The competition between reemission and decline is wavelength dependent. The influence of this factor on the performance of the solar cell is still in discussion.

Silver nanowires having a different size, ranging from 10 to 400 nm, can be used in the instant invention. Both a spinning and a spraying deposition processes are suitable for the current solar cells manufacture process. The density of the silver nanowires on the emitter surface of each solar cell ranges from 10 μg/cm² to 10 mg/cm², which can be controlled by the concentration of the silver nanowires suspension (0.1 mg/ml to 50 mg/ml), the spinning rate (400 rpm to 4000 rpm) or the spraying volume (0.05 ml/cm² to 5 ml/cm²). The idea of using silver nanowires to enlarge the current collection area of the finger electrodes on the emitter side is also suggested to be applied in all kinds of the solar cells, including, but not limited to: silicon cell (e.g. monocrystalline Si cell, multicrystalline Si cell), III-V cell (e.g. GaAs cell, InP cell), polycrystalline thin film cell (e.g. CdTe, CIGS), amorphous Si cell, photochemical cell (e.g. nanocrystalline dye cell), multijunction cell (e.g. GaInP/GaAs cell), and etc.

The advantages of using silver nanowires in the solar cells include, but are not limited to:
1. Ag NWs increase the current collection area of the electrodes, reduce the series resistance, and improve the current and the filled factor of the solar cell.
2. The diameter of the Ag NWs is less than half wavelength of the incident light, which allows the light diffract through nanowires to be absorbed by the solar cell.
3. The excitation of Ag NWs to light includes absorption and scattering. The absorbed light converted to the surface plasmons propagation of the Ag NWs, which can also be released at the ends of the nanowires. The released light can still be absorbed by solar cell to generate the carriers. The scattered light from nanowires can be reflected by the dielectric layers above, to be absorbed by the solar cells again.
4. Ag NWs can be spun or sprayed on the passivation surface of the solar cells. This method minimizes the influence of the new process on the whole production line, better than the methods using lithography which is only available on the flat surface.
5. It can be applied to most kinds of the solar cells.

One embodiment of the instant invention may comprise a method for improving the performance and efficiency of a solar cell comprising the steps of providing a plurality of silver nanowires and depositing a layer of the silver nanowires on an emitter surface of the solar cell. In another embodiment, additional layers of silver nanowires may be deposited on the emitter surface.

The embodiment described above may include the use of silver nanowires having a diameter in the range of 10˜400 nm, and having a length in the range of 1˜200 μm.

The embodiment described above may deposit one or more layers of silver nanowires by either a spinning process or a spraying processes.

The embodiment described above may further comprise the steps of depositing one or more electrodes on the emitter surface wherein the layer of silver nanowires is deposited on the emitter surface before the electrodes, after the electrodes, or a combination thereof.

The embodiment described above may include the use of silver finger electrodes as the electrodes.

The embodiment described above may select the solar cell from the group comprising: a silicon cell (e.g. monocrystalline Si cell, multicrystalline Si cell), a III-V cell (e.g. GaAs cell, InP cell), a polycrystalline thin film cell (e.g. CdTe, GIGS), an amorphous Si cell, a photochemical cell (e.g. nanocrystalline dye cell), or a multijunction cell (e.g. GaInP/GaAs cell).

The embodiment described above may further comprise the steps of providing a silver nanowire suspension having a concentration in the range of 0.1 mg/ml to 50 mg/ml.

### Examples

### Example 1

Preparation of monocrystalline silicon solar cell:
1. Saw damage removal of monocrystalline silicon wafer (125 mm semi-square)
2. Wafer cleaning and emitter diffusion (R_{□}˜60 Ohm/_{□})
3. Evaporation of 2 μm Al on back side
4. Back side contact firing in a belt furnace (temperature ˜900 C.)
5. Dicing the wafer into 2×2 cm² pieces

Electrodes fabrication on the emitter surface:
6. Spinning silver nanowires with the diameter of 300 nm (˜1 mg/ml, in ethanol) on sample frond surface at 1000 rpm for 30 s.
7. Sputtering 50 nm silver on the sample front side through a stencil mask to make silver finger electrodes with 0.2 mm width and 2 mm spacing and bus electrode with 1 mm width.

Characterization of the bared solar cell
8. I-V measurement in a solar simulator (AM1.5 condition), the result is shown in FIG. 5.

TABLE 1

| | Short-circuit current | Open-circuit | Fill factor | |
|---|---|---|---|---|
| NO. | flux (J_{SC}, mA/cm²) | voltage (V_{OC}, mV) | (FF, %) | Efficiency |
| 1 | 16.61769 | 603.2844 | 36.82102 | 3.691378 |
| 2 | 13.48287 | 592.5105 | 33.33344 | 2.662923 |

Note:
sample 2 is the reference only without silver nanowires deposition in the solar cell.

### Example 2

Preparation of monocrystalline silicon solar cell:
1. Saw damage removal of monocrystalline silicon wafer (125 mm semi-square)
2. Wafer cleaning and emitter diffusion (R_{□}˜60 Ohm/_{□})
3. Evaporation of 2 μm Al on back side
4. Back side contact firing in a belt furnace (temperature ˜900 C.)
5. Dicing the wafer into 2×2 cm2 pieces

Electrodes fabrication on the emitter surface:

6. Spraying silver nanowires with the diameter of 300 nm (˜10 mg/ml, in ethanol) on sample frond surface.
7. Sputtering 50 nm silver on the sample front side through a stencil mask to make silver finger electrodes with 0.1 mm width and 2 mm spacing and bus electrode with 1 mm width.

Characterization of the bared solar cell
8. I-V measurement in a solar simulator (AM1.5 condition)

TABLE 2

| | Short-circuit current | Open-circuit | Fill factor | |
|---|---|---|---|---|
| NO. | flux (J_{SC}, mA/cm²) | voltage (V_{OC}, mV) | (FF, %) | Efficiency |
| 3 | 10.35438 | 598.5426 | 35.81143 | 2.219426 |
| 4 | 12.33557 | 532.5077 | 26.98976 | 1.7729 |

Note:
sample 4 is the reference only without silver nanowires deposition in the solar cell.

We claim:

1. A method for improving the performance and efficiency of a solar cell comprising the steps of:
providing a plurality of silver nanowires; and
depositing a layer of said silver nanowires on an emitter surface of said solar cell.

2. The method of claim 1, wherein said silver nanowires having a diameter in the range of 10˜400 nm, and having a length in the range of 1μ200 μm.

3. The method of claim 1, wherein said layer of silver nanowires being deposited by either a spinning process or a spraying processes.

4. The method of claim 1, further comprising the steps of:
depositing one or more electrodes on said emitter surface;
wherein said layer of silver nanowires being deposited on said emitter surface before said electrodes, after said electrodes, or a combination thereof.

5. The method of claim 4, wherein said electrodes being silver finger electrodes.

6. The method of claim 1, wherein said solar cell being selected from the group comprising: a silicon cell (e.g. monocrystalline Si cell, multicrystalline Si cell), a III-V cell (e.g. GaAs cell, InP cell), a polycrystalline thin film cell (e.g. CdTe, CIGS), an amorphous Si cell, a photochemical cell (e.g. nanocrystalline dye cell), or a multijunction cell (e.g. GaInP/GaAs cell).

7. The method of claim 2 further comprising the steps of:
providing a silver nanowire suspension, said silver nanowire suspension having a concentration in the range of 0.1 mg/ml to 50 mg/ml.

8. The method of claim 2, wherein the density of silver nanowires deposited onto the emitter surface of said solar cell ranges from 10 μg/cm² to 10 mg cm².

9. The method of claim 3, wherein said spinning process having a spinning rate in the range of 400 rpm to 4000 rpm for depositing said silver nanowires.

10. The method of claim 3, wherein said spraying process having a spraying volume in the range of 0.05 ml/cm² to 5 ml/cm² for said silver nanowires suspension.
